(19) United States
(12) Patent Application Publication
(10) Pub. No.: US 2026/0173462 A1
(43) Pub. Date: Jun. 18, 2026

(54) SCHOTTKY DIODES WITH EMBEDDED SEMICONDUCTOR STRUCTURES

(71) Applicant: Texas Instruments Incorporated, Dallas, TX (US)

(72) Inventor: Manoj Mehrotra, Dallas, TX (US)

(21) Appl. No.: 18/979,429

(22) Filed: Dec. 12, 2024

(51) Int. Cl. H10D 62/10; H10D 8/01; H10D 8/60; H10D 62/60; H10D 62/83; H10D 62/832

(52) U.S. Cl. CPC H10D 62/107; H10D 8/051; H10D 8/60; H10D 62/125; H10D 62/128; H10D 62/129; H10D 62/60; H10D 62/83; H10D 62/832; H10D 62/8325

(57) ABSTRACT

A Schottky diode includes a semiconductor layer having first, second and third portions, the first and second portions of the semiconductor layer located on opposite lateral sides of the third portion of the semiconductor layer, first and second embedded semiconductor structures extending into the respective first and second portions of a semiconductor layer, the second embedded semiconductor structure having a convex side laterally spaced apart from and facing the first embedded semiconductor structure, and a conductive layer having contiguous first, second and third portions, the first portion of the conductive layer on and contacting the first embedded semiconductor structure, the second portion of the conductive layer on and contacting the second embedded semiconductor structure, and the third portion of the conductive layer on and contacting the third portion of the semiconductor layer.

### BACKGROUND

Diodes provide rectifier components in a variety of electronic systems and devices. Junction diodes use a p-n junction and Schottky diodes include a metal-semiconductor junction. Schottky diodes have lower forward voltage drop than junction diodes and exhibit fast switching speeds and efficient forward current conduction. The advantages of Schottky diodes provide benefits for low power and/or high-frequency applications including power conversion, communications and signal processing. Schottky diodes, however, have higher reverse bias leakage than junction diodes due to lowered barrier height with reverse bias and with temperature.

### SUMMARY

In one aspect, a Schottky diode includes a semiconductor layer having first, second and third portions, the first and second portions of the semiconductor layer located on opposite lateral sides of the third portion of the semiconductor layer. The Schottky diode has a first embedded semiconductor structure extending into the first portion of the semiconductor layer and a second embedded semiconductor structure extending into the second portion of the semiconductor layer. The Schottky diode also includes a conductive layer having contiguous first, second and third portions, the first portion of the conductive layer on and contacting the first embedded semiconductor structure, the second portion of the conductive layer on and contacting the second embedded semiconductor structure, and the third portion of the conductive layer on and contacting the third portion of the semiconductor layer.

In another aspect, a Schottky diode includes a cathode and an anode. The anode includes a conductive layer over a semiconductor layer, a first ohmic junction between the conductive layer and a first embedded semiconductor structure that extends into a first portion of the semiconductor layer, a second ohmic junction between the conductive layer and a second embedded semiconductor structure that extends into a second portion of the semiconductor layer, and a Schottky junction between the conductive layer and a third portion of the semiconductor layer that is laterally between the first and second portions of the semiconductor layer.

In a further aspect, a method includes forming first and second embedded semiconductor structures extending into respective first and second portions of a semiconductor layer, and forming a conductive layer over the semiconductor layer to create a first ohmic junction between a first portion of the conductive layer and the first embedded semiconductor structure, a second ohmic junction between a second portion of the conductive layer and the second embedded semiconductor structure, and a Schottky junction between a third portion of the conductive layer and a third portion of the semiconductor layer that is laterally between the first and second portions of the semiconductor layer.

### BRIEF DESCRIPTION OF THE DRAWINGS

FIG. 1 is a partial sectional side elevation view of an electronic device with a lateral Schottky diode.

FIG. 1A is partial sectional side elevation view of the electronic device of FIG. 1 showing reverse bias depletion.

FIG. 2 is a flow diagram of a method of fabricating an electronic device.

FIGS. 3-9 are partial side elevation and top views of the electronic device of FIGS. 1 and 1A undergoing fabrication processing according to an implementation of the method of FIG. 2.

FIG. 10 is a partial sectional side elevation view of another electronic device with a vertical Schottky diode.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material.

Unless otherwise stated, “about,” “approximately,” or “substantially” preceding a value means +/−10 percent of the stated value. One or more structures, features, aspects, components, etc., may be referred to herein as first, second, third, etc., such as first and second terminals, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

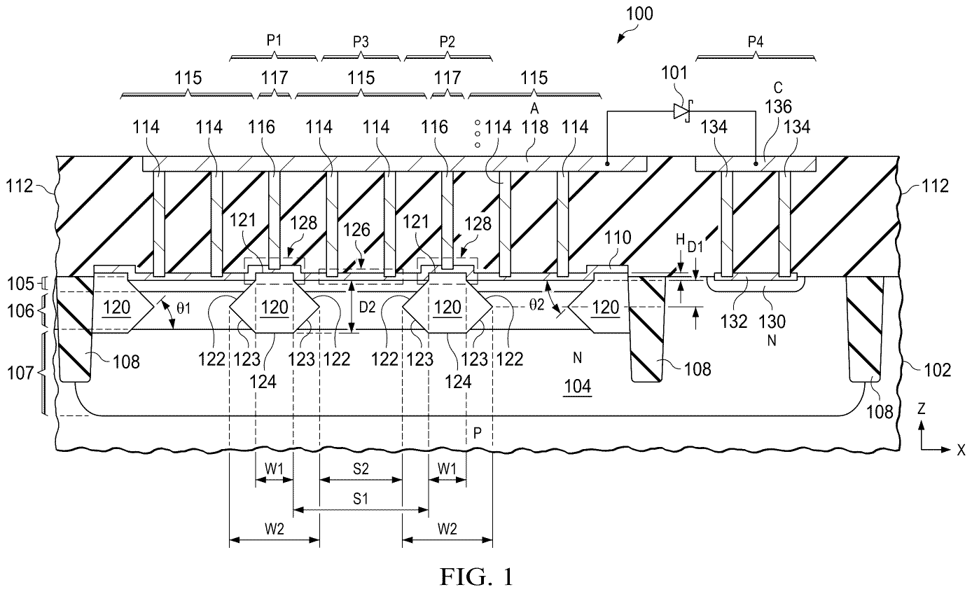

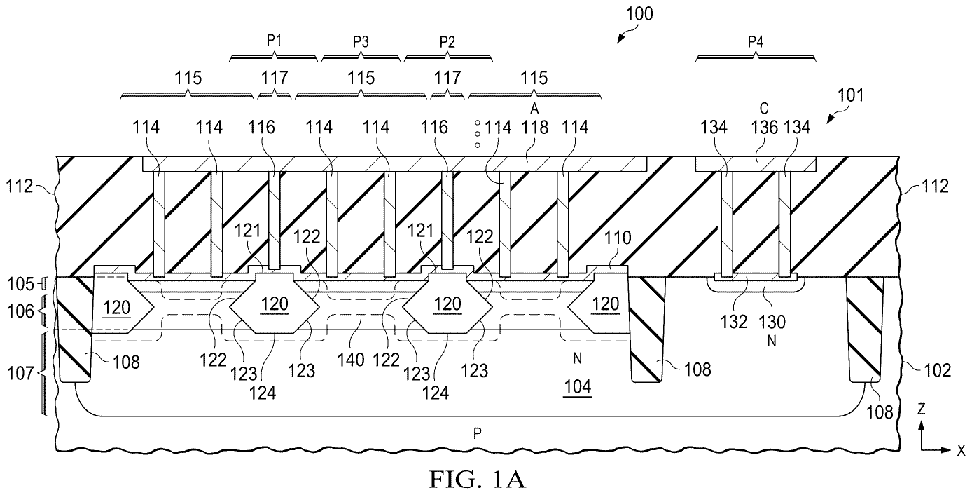

FIGS. 1 and 1A show an electronic device 100 with a lateral Schottky diode 101. The electronic device 100 is shown in an example three-dimensional space with a first direction X, a perpendicular (orthogonal) second direction (e.g., into the page in FIGS. 1 and 1A), and a third direction Z that is perpendicular (orthogonal) to the respective first and second directions. Structures or features along any two of these directions are orthogonal to one another. The electronic device 100 can be an integrated circuit (IC) that includes the Schottky diode 101 and other electronic components (e.g., transistors, resistors, capacitors, inductors, logic circuits, analog amplifiers, etc., not shown) or can be a stand-alone electronic device including the Schottky diode 101 and associated terminal connections for soldering to a host circuit board or installation into a socket (not shown) of a host system.

FIG. 1 schematically illustrates the Schottky diode 101 with an anode terminal A and a cathode terminal C. Conventional Schottky diodes tend to suffer from high reverse bias leakage. This may be attributed to, at least in part, relatively low or small work function or energy barrier that provides beneficial low forward voltage drop performance. In contrast, the Schottky diode 101 has embedded semiconductor structures 120 facilitating formation of depletion regions under reverse bias conditions. The depletion regions may merge (conjoin, combine) to form a contiguous depletion area that at least partially surrounds Schottky junctions (e.g., Schottky junctions 126 described below) to reduce reverse bias leakage. The embedded semiconductor structures 120 may form an ohmic contact (e.g., ohmic contacts 128 described below) with a conductive layer 110.

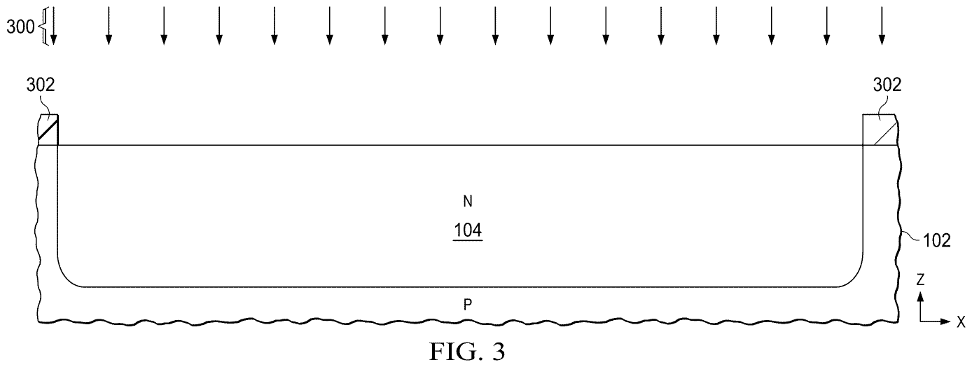

The Schottky diode 101 includes a semiconductor layer 102 with a well or a doped portion 104. In some examples, the doped portion 104 may be formed by one or more ion implantation processes introducing dopants in the doped portion 104 as described in more detail with reference to FIG. 3. As such, the doped portion 104 may also be referred to as an implanted portion 104 (or implanted region 104). In one example, the semiconductor layer 102 is or includes silicon or other suitable semiconductor material. The semiconductor layer 102 in one example is doped silicon with majority carriers of a first conductivity type (e.g., p-type), with boron or other suitable p-type dopants. The implanted portion 104 in one example has majority carriers of a second, opposite, conductivity type (e.g., n-type), with phosphorus or other suitable n-type dopants. In the illustrated example, the first conductivity type is p-type, and the second conductivity type is n-type. In other implementations (not shown), the conductivity types can be reversed (e.g., the first conductivity type can be n-type, and the second conductivity type can be p-type).

The implanted portion 104 of the semiconductor layer 102 has respective first, second and third portions P1, P2 and P3. The first and second portions P1 and P2 of the implanted portion 104 of the semiconductor layer 102 are located on opposite lateral sides of the third portion P3 of the implanted portion 104 of the semiconductor layer 102. The illustrated example has multiple instances of the first, second and third portions P1-P3 laterally between respective pairs of the embedded semiconductor structures 120. This example has four embedded semiconductor structures 120 with three instances of the third portion P3. In other examples, different numbers of two or more embedded semiconductor structures 120 can be used.

The third portions P3 of the implanted portion 104 of the semiconductor layer 102 may include a first region 105, a second region 106, and a third region 107. The first region 105 extends to a surface of the semiconductor layer 102, 104 (e.g., to the top surface). The first region 105 has a first dopant concentration, for example, determined to provide suitable barrier height for good forward bias operation of the Schottky junctions between conductive layer 110 and first regions 105. The second region 106 extends below the first region 105 and may have a second dopant concentration less than the first dopant concentration. In one example, the doping of the second region 106 is determined to facilitate depletion region formation (e.g., conjoining the depletion regions as illustrated in FIG. 1A) under reverse bias conditions so the reverse bias voltage can be substantially blocked by the second region 106—e.g., from reaching the Schottky junctions resulting in barrier height reduction. The third region 107 extends below the second region 106 and may have a third dopant concentration that is greater than the second dopant concentration. In one example, the doping of the third region 107 is determined to reduce the series resistance in current conduction during forward bias operation—e.g., the drift region conduction in the implanted portion 104. In one example, the respective first, second and third regions 105, 106 and 107 of the third portion P3 of the implanted portion 104 of the semiconductor layer 102 are laterally adjacent to the first and second embedded semiconductor structures 120. In another implementation, the third region 107 of the portion P3 of the implanted portion 104 of the semiconductor layer 102 extends vertically downward (e.g., along the third direction Z) past the depth of the embedded semiconductor structures 120.

The illustrated electronic device 100 includes isolation structures 108, such as silicon dioxide (SiO₂) dielectric structures formed as shallow trench isolation (STI) structures, local oxidation of silicon (LOCOS) structures, etc. The illustrated section view of the electronic device 100 shows three isolation structures, which can be formed as a pair of connected laterally encircling or surrounding rings. In the illustrated example, the anode A of the Schottky diode 101 extends between two of the illustrated portions of the isolation structures 108 on the left side of the illustrated view (e.g., laterally surrounded by a first isolation ring), and the cathode C of the Schottky diode 101 extends within a second connected ring formed by the illustrated portions of the isolation structures 108 on the right side of the figure. In another example, the isolation structures 108 can be omitted.

A conductive layer 110 extends over (e.g., directly on and contacting) a portion of the implanted portion 104 of the semiconductor layer 102 and the embedded semiconductor structures 120 to form the anode A connection of the Schottky diode 101. In one example, the conductive layer 110 includes a metal silicide. In another example, the conductive layer 110 includes a metal layer. The conductive layer 110 can be or include any suitable conductive metal material. Some suitable examples include a metal layer that is or includes a metal providing a suitable work function for the Schottky barrier in contact with the implanted portion 104, such as molybdenum, platinum, chromium, tungsten, TiN, TiAl, or the like. In these or other implementations, the conductive layer 110 can include a metal silicide (e.g., palladium silicide, platinum silicide, NiPt silicide with approximately 5% to 10% platinum, Ti-silicide, Co-silicide, Ni-silicide. Tungsten silicide (W-silicide), etc.), in contact with the implanted portion 104 including n-type silicon.

The illustrated electronic device 100 includes embedded semiconductor structures 120 that can induce strain in the implanted portion 104. The strain induced by embedded semiconductor structures 120 may alter the effective mass of carriers changing the carrier transport characteristics of the carriers in the implanted portion 104 as well as over and through the Schottky barrier.

The electronic device 100 further includes a metallization structure with a dielectric layer 112 (e.g., a pre-metal dielectric layer) that extends over the conductive layer 110. Conductive contacts 114 and 116 extend vertically through the dielectric layer 112 (e.g., along the third direction Z) from respective portions of the conductive layer 110 to a conductive metal trace or routing feature 118 (e.g., copper, aluminum, etc.) of the metallization structure. The metallization structure can include further layers or levels above the illustrated dielectric layer 112 and the routing feature 118, for example, including one or more further interlayer or interlevel dielectric (ILD) layers with conductive metal vias and traces or routing features (not shown) to form interconnections between various electronic components of the electronic device 100 including the anode A and the cathode C of the Schottky diode 101.

The example Schottky diode 101 has four embedded semiconductor structures 120 in the implanted region or well 104 of the semiconductor layer 102. Adjacent pairs of the embedded semiconductor structures 120 are laterally spaced apart from one another along the first direction X and are separated by instances of the third portion P3 of the implanted portion 104 of the semiconductor layer 102. In other examples, any integer number of two or more semiconductor structures 120 can be used. The following description refers to the two middle semiconductor structures 120 as respective first and second embedded semiconductor structures 120 and refers to the central third portion P3 between the first and second embedded semiconductor structures 120.

A first embedded semiconductor structure 120 (e.g., the left embedded semiconductor structure 120 of the two middle semiconductor structures 120 in FIGS. 1 and 1A) extends into the first portion P1 of the implanted portion 104 of the semiconductor layer 102 (e.g., downward along the third direction Z). A second embedded semiconductor structure 120 (e.g., the right embedded semiconductor structure 120 of the two middle semiconductor structures 120 in FIGS. 1 and 1A) extends (e.g., downward) into the second portion P2 of the implanted portion 104 of the semiconductor layer 102.

The Schottky diode 101 includes a conductive layer 110 with contiguous first, second and third portions, where the third portion is designated 115 in FIGS. 1 and 1A, and the first and second portions of the conductive layer 110 are designated 117. The first portion 117 of the conductive layer 110 (e.g., the left portion 117 in FIGS. 1 and 1A) is located on and contacting the first embedded semiconductor structure 120. The second portion 117 of the conductive layer 110 (e.g., the right portion 117 in FIGS. 1 and 1A) is located on, and in contact with, the second embedded semiconductor structure 120. The third portion 115 of the conductive layer 110 (e.g., the middle third portion 115 in FIGS. 1 and 1A) is located on, and in contact with, the third portion P3 of the implanted portion 104 of the semiconductor layer 102.

A first conductive contact 116 is located on and contacts the first portion 117 of the conductive layer 110 above the first embedded semiconductor structure 120. A second conductive contact, also referenced 116 in FIGS. 1 and 1A, is located on, and in contact with, the second portion 117 of the conductive layer 110 above the second embedded semiconductor structure 120. A third conductive contact 114 is located on, and in contact with, the third portion 115 of the conductive layer 110 above the third portion P3 of the implanted portion 104 of the semiconductor layer 102. The first portion 117 of the conductive layer 110 forms a first ohmic junction (ohmic contact) 128 between the conductive layer 110 and the first embedded semiconductor structure 120. The second portion 117 of the conductive layer 110 forms a second ohmic junction 128 (ohmic contact) between the conductive layer 110 and the second embedded semiconductor structure 120. The third portion 115 of the conductive layer 110 forms a Schottky junction 126 between the conductive layer 110 and the third portion P3 of the implanted portion 104 of the semiconductor layer 102 that is laterally between the first and second embedded semiconductor structures 120.

In some examples, the first and second embedded semiconductor structures 120 may have raised top portions 121 with a height denoted as H (e.g., protruded above the surface of the doped portion 104) as shown in FIGS. 1 and 1A. The raised top portions 121 may increase an area contacting the conductive layer 110 (e.g., first and second portions 117 of the conductive layer 110) to reduce the contact resistance of the ohmic contacts 128. In some examples, top surfaces of the embedded semiconductor structures 120 may be flush with the surface of the doped portion 104. In some examples, top surfaces of the embedded semiconductor structures 120 may be recessed with respect to the surface of the doped portion 104. Moreover, the first and second embedded semiconductor structures 120 may have convex lateral sides formed by angled side portions 122 and 123, as well as a bottom 124 in the respective first and second portions P1 and P2 of the implanted portion 104 of the semiconductor layer 102. As shown in FIG. 1, the side portions 123 of each embedded semiconductor structure 120 extend upward from the bottom 124 and laterally outwardly at a first angle θ1 (e.g., approximately 45°), and the side portions 122 extend upward from the side portions 123 to the top portion 121 at a second angle θ2 (e.g., approximately 45°) to form convex lateral sides of the embedded semiconductor structures 120.

The embedded semiconductor structures 120 may include one or more suitable semiconductor materials or alloys thereof. In one example, the embedded semiconductor structures 120 are or include silicon (e.g., Si). In this or another example, the embedded semiconductor structures 120 are or include silicon germanium of any suitable stoichiometry (e.g., SiGe). In these or another example, the embedded semiconductor structures 120 are or include silicon carbide of any suitable stoichiometry (e.g., SiC).

In the illustrated example, the embedded semiconductor structures 120 each have a convex side laterally spaced apart from and facing another one of the embedded semiconductor structures 120. The example second embedded semiconductor structure 120 has a convex side laterally spaced apart from and facing the first embedded semiconductor structure 120, and the first embedded semiconductor structure 120 has a convex side laterally spaced apart from and facing the second embedded semiconductor structure 120. In this example, moreover, the first and second embedded semiconductor structure 120 each have laterally opposite convex sides. In other examples, one or more of the embedded semiconductor structure 120 can have a non-convex lateral side. The embedded semiconductor structures 120 in one example extend as strips or fingers along the second direction (e.g., into and out of the page and perpendicular to the X and Z directions in the illustrated section view). In one example, the laterally outward embedded semiconductor structures 120 extend to the ring-shaped isolation structure 108 along the first direction X, and the finger structures extend along the second direction to the encircling portions of the isolation structure 108 (not shown).

As further shown in FIG. 1, the first and second embedded semiconductor structures 120 each have a lateral width (e.g., along the first direction X in the illustrated orientation) that increases (e.g., along the side portions 122) from a first width W1 at a surface of the implanted portion 104 of the semiconductor layer 102 to a second with W2 greater than the first width W1 at a first distance D1 from the surface of the semiconductor layer 102, 104. The lateral width of the first and second embedded semiconductor structures 120 then decreases (e.g., along the side portions 123) to a third width (e.g., equal to the first width W1 in the illustrated example) at a second distance D2 greater than the first distance D1 from the surface of the implanted portion 104 of the semiconductor layer 102.

The illustrated embedded semiconductor structures 120 have a generally diamond-shaped profile with a raised top portion 121, laterally opposite convex sides and a flat bottom 124. The transitions between the portions of the profile may, but need not, have pointed features, and the profile transitions can be curvilinear. The portions of the profile generally have linear sides in the illustrated example. In other examples, the portions of the profile can have curved, nonlinear, piecewise linear, or other shapes (not shown). In certain implementations, moreover, the Schottky junctions 126 extend across a first distance S1 (e.g., along the first direction X in FIG. 1), the convex lateral sides of the embedded semiconductor structures 120 are spaced apart from one another by a second distance S2 that is less than the first distance S1. The overall size of the Schottky diode 101 can be reduced by controlling the lateral widths of the Schottky junctions 126 (e.g., S1) to be wider than lateral widths of the ohmic junctions 128 (e.g., W1) (e.g., S1 is greater than W1 in FIG. 1). In one implementation, the first width W1 can be reduced to a value according to lithographic patterning capability of a given fabrication process and equipment. For example, W1 may be approximately 30-100 nm and the second width W2 can be greater than W1 while facilitating depletion region merging during reverse bias operation, such as approximately 90-160 nm in one example. The distances S1 and S2 in a given implementation can be determined based on the dopant concentration of the second region 106 of the implanted portion 104. For example, S2 can be approximately 30-100 nm and S1 can be approximately 90-160 nm.

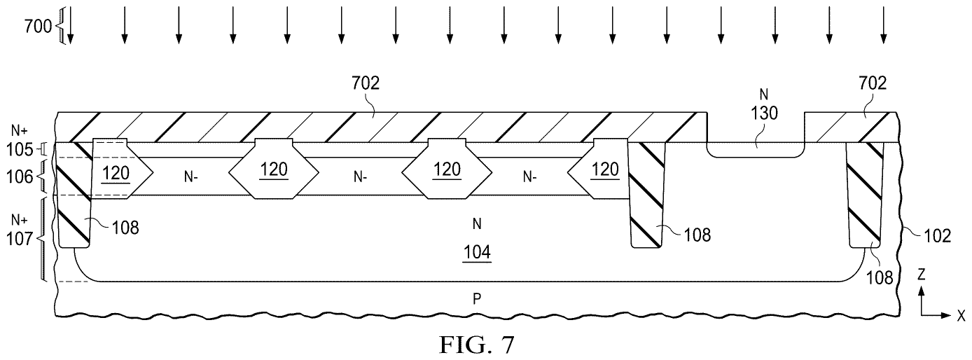

The cathode C of the Schottky diode 101 is formed by an doped region 130 in a fourth portion P4 of the implanted portion 104 of the semiconductor layer 102. In some examples, the doped region 130 may be formed by one or more ion implantation process steps introducing dopants in the doped region 130 as described in more detail herein with reference to FIG. 7. As such, the doped region 130 may also be referred to as an implanted region 130. The fourth portion P4 is laterally spaced apart from the first, second, and third portions P1, P2, P3 of the implanted portion 104 of the semiconductor layer 102. The implanted region 130 includes majority carriers of the second conductivity type (e.g., n-type, such as phosphorus, arsenic, etc.)—e.g., the same conductivity type as the implanted portion 104. The fourth portion P4 the implanted portion 104 of the semiconductor layer 102 forms the cathode C of the Schottky diode 101. In one example, implanted region 130 has a higher concentration of dopants of the second conductivity type than the remaining part of the implanted portion 104. Another conductive layer 132 may overlie and extend on the top surface of the implanted region 130. The metallization structure includes further conductive metal contacts 134 (e.g., tungsten, etc.) that extend from the conductive layer 132 upward (e.g., along the third direction Z) to a conductive metal trace or routing feature 136 of the metallization structure (e.g., copper, aluminum, etc.) to provide a cathode terminal connection of the Schottky diode 101.

The embedded semiconductor structures 120 in one example have majority carriers of the first conductivity type (e.g., p-type) and a first carrier concentration suitable to form the ohmic junctions 128. The implanted portion 104 of the semiconductor layer 102 has majority carriers of the opposite second conductivity type (e.g., n-type) and a second carrier concentration. In some examples, the second carrier concentration is less than the first carrier concentration to facilitate formation of the depletion regions that at least partially surround the embedded semiconductor structures 120. The first portion 117 of the conductive layer 110 forms the first ohmic junction 128 with the first embedded semiconductor structure 120. The second portion 117 of the conductive layer 110 forms the second ohmic junction 128 with the second embedded semiconductor structure 120. The third portion 115 of the conductive layer 110 forms the Schottky junction 126 with the third portion P3 of the implanted portion 104 of the semiconductor layer 102. The third portion P3 of the implanted portion 104 of the semiconductor layer 102 is laterally between the first and second portions P1, P2 of the implanted portion 104 of the semiconductor layer 102.

The embedded semiconductor structures 120 facilitate good reverse bias performance with reduced reverse leakage. In the illustrated example, the convex lateral sides of the embedded semiconductor structures 120 facilitate lateral merging of individual depletion regions formed around the embedded semiconductor structures 120 when the Schottky diode 101 is reversed biased. In other words, the example diamond shaped embedded semiconductor structures 120 facilitates lateral merging of individual depletion regions (e.g., to form barrier region or pinch off region) such that the Schottky junction 126 (and associated Schottky barrier) can be shielded from reverse bias. Moreover, the example diamond shaped embedded semiconductor structures 120 maximizes the area of Schottky junction 126 for forward bias operation where low forward voltage drop is advantageous for reducing power consumption. In addition, the doping of the regions 105, 106 and 107 are configured to provide beneficial forward and reverse bias operation characteristics of the Schottky diode 101.

FIG. 1A shows the Schottky diode in reverse biased operation. Reverse bias applied to anode A forms a depletion region 140 as a result of merging local depletion regions at the p-n junctions of the p-type embedded semiconductor structures 120 and the surrounding n-type silicon of the implanted portion 104 of the semiconductor layer 102. As reverse bias voltage is applied, depletion initially occurs along the p-n junctions of the p-type embedded semiconductor structures 120 and the surrounding n-type implanted portion 104, and the local depletion regions from adjacent embedded semiconductor structures 120 merge to form the depletion region 140 (e.g., barrier regions or pinch-off regions) extending between the laterally spaced embedded semiconductor structures 120 when the reverse bias voltage is sufficiently high. At least a portion of the reverse bias is then supported by expanding depletion region 140 that operates to shield the Schottky junction 126 (and associated barrier height) from the reverse bias. In this manner, barrier height lowering and associated excessive reverse-bias leakage may be ameliorated.

In reverse bias operation, the depletion region 140 at least partially supports the reverse bias voltage, and thereby reduces the reverse bias across the Schottky junction 126 in the third portion P3 of the implanted portion 104 of the semiconductor layer 102 and mitigates the Schottky barrier height reduction during reverse bias operation. Because the reverse bias voltage across the Schottky junction 126 is reduced, the reverse bias leakage of the Schottky diode 101 is reduced. The Schottky diode 101 thus provides the low forward bias voltage drop and power efficiency advantages under a forward bias condition, together with low reverse bias leakage under a reverse bias condition to provide an enhanced solution for communications, power conversion, and other circuit or system applications. In one implementation, the first region 105 can have a dopant concentration of approximately 1×10¹⁵ to 1×10¹⁸ cm⁻³ to provide a desired Schottky barrier height during forward bias operation. The dopant concentration of the second region 106 in one example can be tailored for reverse bias operation to pinch off/blocking the reverse bias voltage, for example, approximately 1×10¹⁴ to 1×10¹⁶ cm⁻³, and the dopant concentration of the third region 107 can be tailored for reducing the series resistance during forward bias operation (e.g., drift region conduction), such as approximately 1×10¹⁵ to 1×10¹⁸ cm⁻³.

In some examples, one or more materials for the embedded semiconductor structures 120 may be determined based on the conductivity type (e.g., n-type or p-type) of the implanted portion 104 of the semiconductor layer 102. For example, using an n-type implanted portion 104, suitable p-type materials for the embedded semiconductor structures 120 can include p-doped SiGeC, p-doped SiGe, SiGeB (e.g., boron doped silicon germanium), SiB (e.g., boron doped silicon), such as a single layer or multilayer structure with one or more of these materials deposited in a cavity formed during manufacturing. In further examples, using a p-type implanted portion 104, suitable n-type materials for the embedded semiconductor structures 120 can include n-doped SiP (e.g., phosphorus doped silicon), n-doped SiC, SiAs (e.g., arsenic doped silicon), SiCP (e.g., phosphorus doped silicon carbide), SiCAs (e.g., arsenic doped silicon carbide), etc., such as a single layer or multilayer structure with one or more of these materials deposited in a cavity formed during manufacturing. The embedded semiconductor structures 120 in one example are doped in-situ during deposition process to fill the cavities formed during fabrication. In this or another example, the embedded semiconductor structures 120 can be doped based on one or more implantation process steps - e.g., during a source/drain implant step, alone or in combination with in-situ doping during deposition of the embedded semiconductor structures 120. The embedded semiconductor structures 120 may be doped to improve the contact resistance and to form junction regions with respect to the implanted portion 104 - e.g., to facilitate depletion region formation in the implanted portion 104 under reverse bias conditions.

The first region 105 has a first dopant concentration, for example, determined to provide suitable barrier height for good forward bias operation. The second region 106 extends below the first region 105 and has a second dopant concentration less than the first dopant concentration. In one example, the doping of the second region 106 is determined to facilitate forming depletion regions (pinch-off regions) for reverse bias conditions so the reverse bias voltage can be substantially blocked in the second region 106. The third region 107 extends below the second region 106 and has a third dopant concentration that is greater than the second dopant concentration. In one example, the doping of the third region 107 is determined to reduce the series resistance in current conduction during forward bias operation - e.g., the drift region conduction. In one example, the respective first, second and third regions 105, 106 and 107 of the third portion P3 of the implanted portion 104 of the semiconductor layer 102 are laterally adjacent to the first and second embedded semiconductor structures 120. In another implementation, the third region 107 of the portion P3 of the implanted portion 104 of the semiconductor layer 102 extends vertically downward (e.g., along the third direction Z) past the depth of the embedded semiconductor structures 120.

The example Schottky diode 101 in FIGS. 1 and 1A includes the implanted portion 104 having n-type majority carriers, in combination with p-type doped embedded semiconductor structures 120 (e.g., p-type doped SiGe). Moreover, the conductive layer 110 of the example Schottky diode 101 may include a metal silicide (e.g., NiPt silicide) or a suitable p-type work function metal (e.g., TiN). In other implementations, a p-type majority carrier well or implanted region 104 can be used, in combination with n-type doped embedded semiconductor structures 120 (e.g., n-type doped SiC). In such implementations, a conductive layer 110 may include a suitable n-type work function metal (e.g., TiAl).

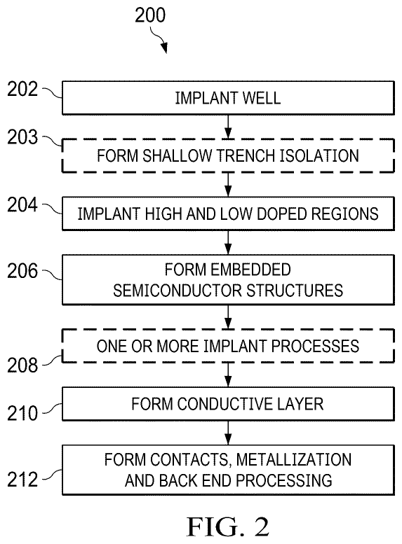

Referring now to FIGS. 2-9, FIG. 2 shows a method 200 of fabricating an electronic device and FIGS. 3-9 illustrate one example of the above described electronic device 100 undergoing fabrication processing according to one implementation of the method 200. The method 200 begins at 202 in FIG. 2 with implanting n-type dopants (e.g., phosphorus, etc.). FIG. 3 shows one example, in which an implantation process 300 is performed with an implant mask 302. The process 300 implants n-type dopants (e.g., phosphorus, etc.) into exposed portions of the p-type semiconductor layer 102 in order to form the implanted region 104.

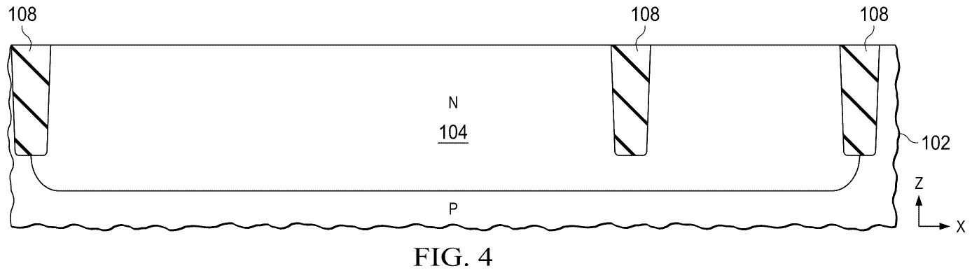

In one implementation, the method 200 includes isolation processing at 203 in FIG. 2. FIG. 4 shows one example, in which a shallow trench isolation (STI) structure 108 has been formed. The STI structure 108 extends into the semiconductor layer 102 including portions that extend into the implanted region 104. In another implementation, a different type of isolation processing can be performed (e.g., local oxidation of silicon, LOCOS, etc.). In a different implementation, the isolation processing at 203 in FIG. 2 can be omitted.

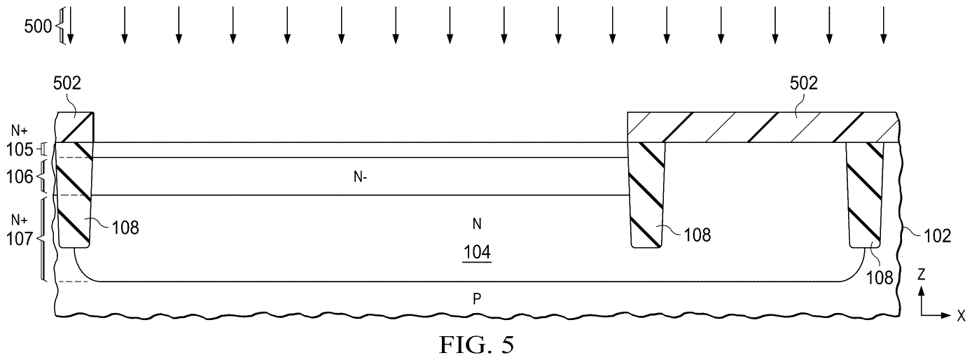

The method 200 in one example continues at 204 in FIG. 2 with further (e.g., n-type) implantations in the anode portion of the structure to form the differently doped regions 105, 106 (and 107 in some examples) as described above. FIG. 5 shows one example, in which one or more implantation processes 500 are performed using an implant mask 502 to form the implanted regions 105 and 106 within the anode portion of the implanted region 104. As previously described, the first region 105 extends to the top surface of the exposed semiconductor layer 102, 104 and has a first dopant concentration, for example, determined to provide suitable barrier height of the subsequently completed Schottky junctions for good forward bias operation. The second region 106 extends below the first region 105 and has a second dopant concentration less than the first dopant concentration. In one example, the doping of the second region 106 is determined to facilitate depletion region formation under reverse bias conditions so the reverse bias voltage may be substantially blocked in the second region 106. The third region 107 extends below the second region 106 and has a third dopant concentration that is greater than the second dopant concentration. In some examples, the third dopant concentration can be set during implantation of the implanted region 104 (e.g., at 202 in FIG. 2). In some examples, the implantation processes 500 forms the third region 107 (in conjunction with the implantation of the implanted region 104) in addition to the first and second regions 105, 106.

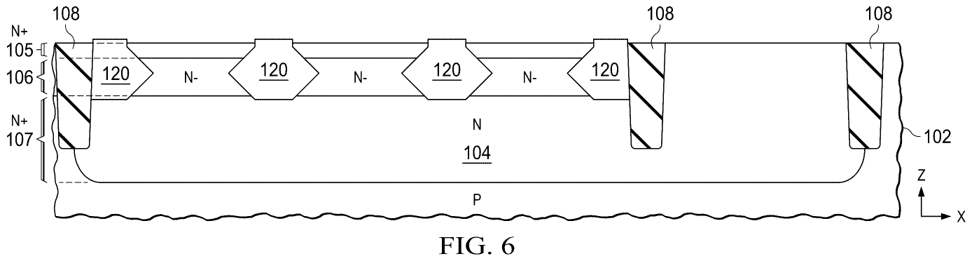

The method 200 continues at 206 in FIG. 2 with forming the embedded semiconductor structures 120. FIG. 6 shows one example following formation of the embedded semiconductor structures 120 that extend into respective of the implanted portion 104 of the semiconductor layer 102. Any suitable embedded semiconductor structure formation can be used at 206. In one example, the formation at 206 can include etching trenches (e.g., cavities) having outwardly extending sidewalls (e.g., convex lateral sides), followed by deposition of semiconductor material into the cavities. The semiconductor material may be in-situ doped during the deposition (or epitaxial growth process). Alternatively, the semiconductor material may be doped based on post deposition implantation using a suitable implantation mask (not shown). In some examples, both in-situ doping and post deposition implantation may be used. The processing at 206 in one example includes etching openings with laterally concave profiles extending into the respective first and second portions P1 and P2 of the implanted portion 104 of the semiconductor layer 102 and embedding (depositing, filling, growing) semiconductor material 120 in the first and second openings to form the embedded semiconductor structures having convex lateral sides as described above.

At 208 in FIG. 2, the method 200 in one example includes one or more implantation process steps—e.g., source-drain implantation. FIG. 7 shows one example, in which an implantation process 700 is performed using an implant mask 702. The process 700 in one example implants n-type dopants (e.g., phosphorus, etc.) to form the implanted region 130.

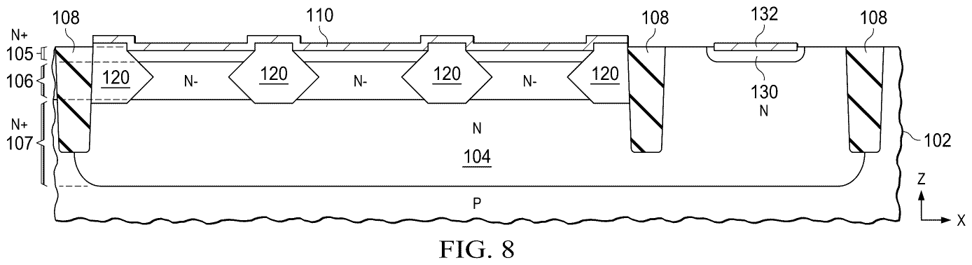

The method 200 continues at 210 in FIG. 2 with forming conductive material of the conductive layer 110 and the conductive layer 132. In one example, a metal deposition process is performed that selectively forms conductive material, such as deposition, followed by patterning to form the conductive structures 110 and 132. FIG. 8 shows one example, in which a silicidation process has been performed to form the conductive layer 110 and the conductive layer 132 of metal silicide materials as described above over the implanted portion 104 of the semiconductor layer 102 as well as over the implanted region 130. The processing at 210 forms the conductive layer 110 over the implanted portion 104 of the semiconductor layer 102 to create the Schottky junctions (e.g., Schottky junction 126) as well as the ohmic junctions (e.g., ohmic junctions 128) for the anode portion of the subsequently completed Schottky diode.

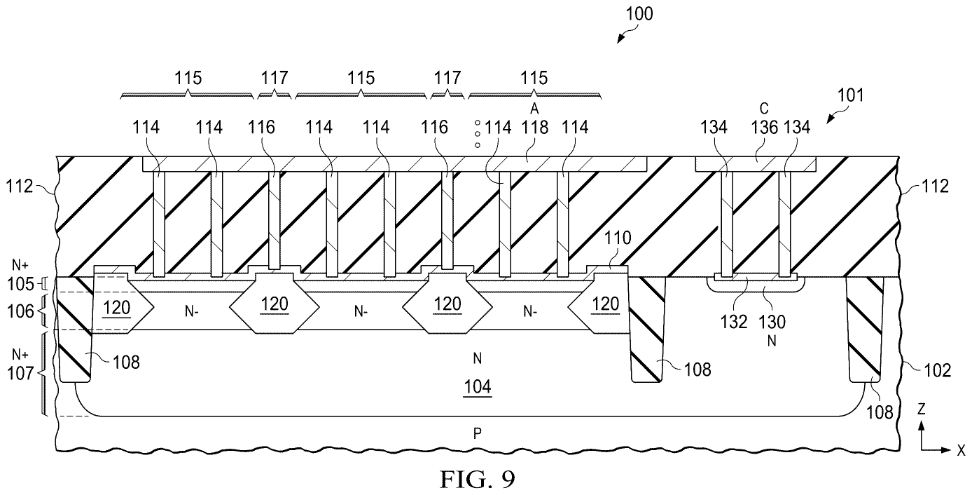

The method 200 in FIG. 2 continues at 212 with forming contacts in a metallization structure, along with other backend processing. FIG. 9 shows one example, in which the metallization structure has been formed with the anode contacts 114 and 116 as well as the cathode contacts 134 to complete the example lateral Schottky diode 101.

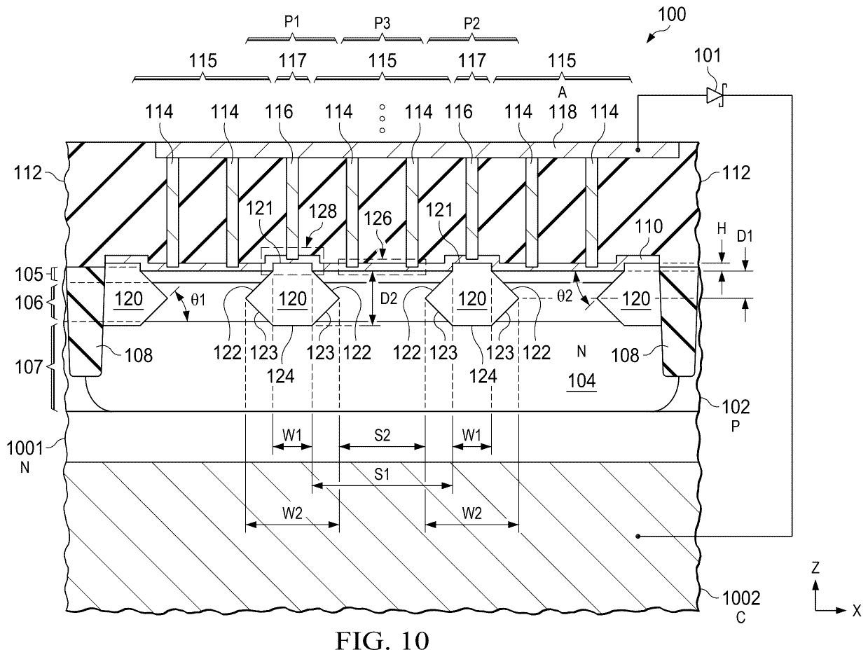

Referring now to FIG. 10, another implementation provides an example vertical Schottky diode. The Schottky diode 101 in FIG. 10 includes similarly numbered structures, features, components, etc. 102, 104-108, 110, 112, 114-118, 120-124, 126, 128, A, C, P1-P3, H, D1, D2, W1, W2, S1, S2, θ1, and θ2 as described above in connection with the electronic device 100 of FIG. 1. In this example, the cathode C is beneath the semiconductor layer 102, for example, including back side metallization with a metal layer 1002 (e.g., copper, aluminum, etc.) and an n-type doped region 1001 (e.g., extending along the third direction Z between the doped region 104 and the back side metal layer 1002) to provide a cathode C for the Schottky diode 101. The n-type doped region 1001 may have a dopant concentration similar to the doped region 130. Moreover, the n-type doped region 1001 forms an ohmic contact with the back side metal layer 1002.

Modifications are possible in the described examples, and other implementations are possible, within the scope of the claims.

What is claimed is:

1. A Schottky diode, comprising:
a semiconductor layer having first, second and third portions, the first and second portions of the semiconductor layer located on opposite lateral sides of the third portion of the semiconductor layer;
a first embedded semiconductor structure extending into the first portion of the semiconductor layer;
a second embedded semiconductor structure extending into the second portion of the semiconductor layer; and
a conductive layer having contiguous first, second and third portions, the first portion of the conductive layer on and contacting the first embedded semiconductor structure, the second portion of the conductive layer on and contacting the second embedded semiconductor structure, and the third portion of the conductive layer on and contacting the third portion of the semiconductor layer.

2. The Schottky diode of claim 1, wherein the second embedded semiconductor structure has a convex side laterally spaced apart from and facing the first embedded semiconductor structure.

3. The Schottky diode of claim 2, wherein the first embedded semiconductor structure has a convex side laterally spaced apart from and facing the second embedded semiconductor structure.

4. The Schottky diode of claim 1, wherein the first and second embedded semiconductor structure each have laterally opposite convex sides.

5. The Schottky diode of claim 1, wherein the first and second embedded semiconductor structures each have a lateral width that increases from a first width at a surface of the semiconductor layer to a second with greater than the first width at a first distance from the surface of the semiconductor layer and then decreases to a third width at a second distance greater than the first distance from the surface of the semiconductor layer.

6. The Schottky diode of claim 1, wherein:
the first and second embedded semiconductor structures have majority carriers of a first conductivity type and a first carrier concentration; and
the semiconductor layer has majority carriers of an opposite second conductivity type and a second carrier concentration that is less than the first carrier concentration.

7. The Schottky diode of claim 1, wherein the conductive layer includes a metal silicide.

8. The Schottky diode of claim 1, wherein the conductive layer includes a metal layer.

9. The Schottky diode of claim 1, wherein the conductive layer forms an anode of the Schottky diode.

10. The Schottky diode of claim 1, further comprising a fourth portion of the semiconductor layer that is laterally spaced apart from the first, second, and third portions of the semiconductor layer.

11. The Schottky diode of claim 10, wherein the fourth portion the semiconductor layer forms a cathode of the Schottky diode.

12. The Schottky diode of claim 1, further comprising:
a first conductive contact on and contacting the first portion of the conductive layer above the first embedded semiconductor structure;
a second conductive contact on and contacting the second portion of the conductive layer above the second embedded semiconductor structure; and
a third conductive contact on and contacting the third portion of the conductive layer above the third portion of the semiconductor layer.

13. The Schottky diode of claim 1, wherein:
the first portion of the conductive layer forms an ohmic junction with the first embedded semiconductor structure;
the second portion of the conductive layer forms an ohmic junction with the second embedded semiconductor structure; and
the third portion of the conductive layer forms a Schottky junction with the third portion of the semiconductor layer.

14. The Schottky diode of claim 1, wherein the first and second embedded semiconductor structures each include one of silicon, silicon germanium and silicon carbide.

15. The Schottky diode of claim 1, wherein the third portion of the semiconductor layer includes a first region extending to a surface of the semiconductor layer and having a first dopant concentration, a second region below the first region and having a second dopant concentration less than the first dopant concentration, and a third region below the second region and having a third dopant concentration that is greater than the second dopant concentration, wherein the first, second and third regions (105, 106, 107) of the third portion of the semiconductor layer are laterally adjacent to the first and second embedded semiconductor structures.

16. A Schottky diode, comprising
a cathode; and
an anode, including:
a conductive layer over a semiconductor layer;
a first ohmic junction between the conductive layer and a first embedded semiconductor structure that extends into a first portion of the semiconductor layer;
a second ohmic junction between the conductive layer and a second embedded semiconductor structure that extends into a second portion of the semiconductor layer; and
a Schottky junction between the conductive layer and a third portion of the semiconductor layer that is laterally between the first and second portions of the semiconductor layer.

17. The Schottky diode of claim 16, wherein the second embedded semiconductor structure has a convex side laterally spaced apart from and facing the first embedded semiconductor structure.

18. The Schottky diode of claim 17, wherein the first embedded semiconductor structure has a convex side laterally spaced apart from and facing the convex side of the second embedded semiconductor structure.

19. The Schottky diode of claim 16, wherein the first and second embedded semiconductor structure each have laterally opposite convex sides.

20. The Schottky diode of claim 16, wherein the first and second embedded semiconductor structures each include one of silicon, silicon germanium and silicon carbide.

21. A method, comprising:
forming first and second embedded semiconductor structures extending into respective first and second portions of a semiconductor layer; and
forming a conductive layer over the semiconductor layer to create a first ohmic junction between a first portion of the conductive layer and the first embedded semiconductor structure, a second ohmic junction between a second portion of the conductive layer and the second embedded semiconductor structure, and a Schottky junction between a third portion of the conductive layer and a third portion of the semiconductor layer that is laterally between the first and second portions of the semiconductor layer.

22. The method of claim 21, further comprising:
implanting a first region of the third portion of the semiconductor layer with dopants having a first dopant concentration;
implanting a second region the third portion of the semiconductor layer below the first region with dopants having a second dopant concentration less than the first dopant concentration; and
implanting a third region of the third portion of the semiconductor layer below the second region with dopants having a third dopant concentration greater than the second dopant concentration.

23. The method of claim 21, wherein forming the first and second embedded semiconductor structures includes etching first and second openings with laterally concave profiles extending into the respective first and second portions of the semiconductor layer and embedding semiconductor material in the first and second openings.
